(19) United States
(12) Patent Application Publication
(10) Pub. No.: US 2025/0282904 A1
(43) Pub. Date: Sep. 11, 2025

(54) RESIN COMPOSITION FOR FORMING PHASE-SEPARATED STRUCTURE, METHOD FOR PRODUCING STRUCTURE HAVING PHASE-SEPARATED STRUCTURE, AND BLOCK COPOLYMER

(71) Applicant: TOKYO OHKA KOGYO CO., LTD., Kawasaki-shi (JP)

(72) Inventors: Shota IINO, Kawasaki-shi (JP); Ryutaro SUGAWARA, Kawasaki-shi (JP); Ken MIYAGI, Kawasaki-shi (JP)

(21) Appl. No.: 19/069,711

(22) Filed: Mar. 4, 2025

(30) Foreign Application Priority Data
Mar. 6, 2024 (JP) 2024-033777

(51) Int. Cl. C08F 297/02; C08F 12/08; C08F 20/14; C08F 220/18; G03F 7/00

(52) U.S. Cl. CPC C08F 297/026; C08F 12/08; C08F 20/14; C08F 220/1806; G03F 7/0002

(57) ABSTRACT

A resin composition for forming a phase-separated structure which is excellent in vertical orientation and in which the occurrence of defects is suppressed, a method for producing a structure having a phase-separated structure using the same, and a block copolymer. The composition includes a block copolymer having a first block and a second block, the first block including a polymer having a repeating structure of a constituent unit represented by the following general formula (b1), the second block including a random copolymer having a structure in which a constituent unit represented by the following general formula (b2m) and a constituent unit represented by the following general formula (b2g) are randomly arranged

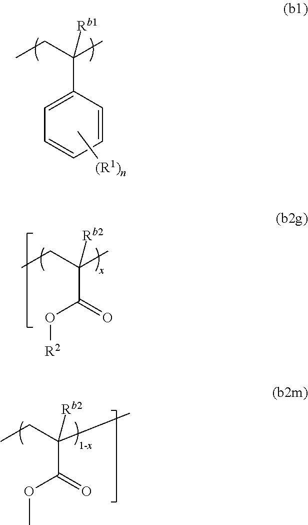

This application claims priority to Japanese Patent Application No. 2024-033777, filed Mar. 6, 2024, the entire content of which is incorporated herein by reference.

### BACKGROUND OF THE INVENTION

### Field of the Invention

The present invention relates to a resin composition for forming a phase-separated structure, a method for producing a structure having a phase-separated structure, and a block copolymer.

### Related Art

In recent years, following further miniaturization of a large-scale integrated circuit (LSI), a technique for processing a finer structure has been demanded. In response to this demand, a technique has been developed to form finer patterns by utilizing a phase-separated structure formed by directed self-assembly of block copolymers in which mutually incompatible blocks are bonded to each other (see, for example, Patent Document 1).

The block copolymers separate (phase-separate) into micro-regions due to repulsion between the mutually incompatible blocks, then are subjected to heat treatment or the like to form a structure having a regular periodic structure. The periodic structure may be a cylinder (columnar), lamella (plate-like), sphere (spherical), or the like.

To use this phase-separated structure of block copolymers, it is essential that self-assembled nanostructures formed by micro-phase separation be formed only in specific regions and be arranged in a desired direction. To control a position and an orientation of these nanostructures, processes such as graphene epitaxy, which controls phase separation patterns by guiding patterns, and chemical epitaxy, which controls phase separation patterns by differences in a chemical state of a substrate, have been proposed (see, for example, Non-Patent Document 1).

The block copolymer forms a structure having a regular periodic structure by phase separation. The phrase “structural period” means a period of a phase structure observed when a structure having a phase-separated structure is formed and refers to a sum of lengths of phases incompatible with each other. In a case where a phase-separated structure forms a cylinder structure perpendicular to a surface of a substrate, a structural period (L₀) is a distance between centers (pitch) of two adjacent cylinder structures.

It is known that the structural period (L₀) is determined by inherent polymerization properties such as a degree of polymerization N or the Flory-Huggins interaction parameter χ. That is, the larger the product of χ and N “χ·N”, the greater the mutual repulsion between different blocks in the block copolymer. Therefore, in the case of χ·N>10.5 (hereinafter, referred to as “intensity separation limit”), repulsion between different kinds of blocks in the block copolymer is large, leading to a stronger tendency to cause phase separation. Accordingly, at the intensity separation limit, the structural period is approximately N^{2/3}·χ^{1/6} and a relationship expressed in the following formula (1) is satisfied. That is, the structural period is proportional to the degree of polymerization N, which correlates with a molecular weight and a molecular weight ratio between different blocks.

$${L}_{0} ∝ a \cdot {N}^{2 / 3} \cdot {χ}^{1 / 6} \qquad ( 1 )$$

[wherein L₀ denotes a structural period, a is a parameter indicating a size of a monomer, N denotes a degree of polymerization, and χ is an interaction parameter, in which a higher value means a higher phase separation performance.]

Accordingly, the structural period (L₀) can be controlled by adjusting a composition and a total molecular weight of a block copolymer. Therefore, to form a structure having a relatively large L₀ by utilizing a phase-separated structure formed by directed self-assembly of block copolymers, a method for increasing a molecular weight of the block copolymers is considered.
Patent Document 1: Japanese Unexamined Patent Application, Publication No. 2008-36491
Non-Patent Document 1: Proc. SPIE 7637, Alternative Lithographic Technologies II, 76370G (1 Apr. 2010)

### SUMMARY OF THE INVENTION

However, when the molecular weight of the block copolymer is simply increased, a phase separation rate is reduced, and as a result, there may be a problem that the vertical orientation is not exhibited or a phase-separated structure having many defects is exhibited. The term “defect” refers to, for example, all failures detected at the time of observing a phase separation pattern from directly above by a scanning electron microscope or the like. The failures refer to, for example, a failure caused by adhesion of foreign substances or precipitates such as scum (resin composition residue), bubbles, or dust after the formation of the phase separation pattern to a surface of the phase separation pattern, a failure related to a pattern shape such as a bridge between line patterns and hole filling of a contact hole pattern, color unevenness of the pattern, or the like.

The present invention has been made in view of the above circumstances, and an object of the present invention is to provide a resin composition for forming a phase-separated structure capable of forming a phase-separated structure which is excellent in vertical orientation and of which occurrence of defects is suppressed, a method for producing a structure having a phase-separated structure using the same, and a block copolymer for use in the resin composition for forming a phase-separated structure.

As a result of intensive studies to solve the above problem, the present inventors have found that the above problem can be solved by using a predetermined block copolymer, and have completed the invention. Specifically, the present invention provides the following aspects.

A first aspect relates to a resin composition for forming a phase-separated structure, the resin composition containing: a block copolymer having a first block and a second block,
the first block being composed of a polymer having a repeating structure of a constituent unit represented by the following general formula (b1),
the second block being composed of a random copolymer having a structure in which a constituent unit represented by the following general formula (b2m) and a constituent unit represented by the following general formula (b2g) are randomly arranged,

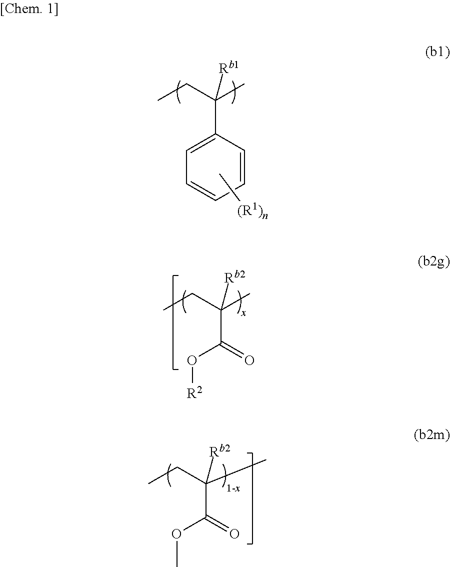

[wherein in formular (b1), R¹ is an alkyl group, R^{b1} is a hydrogen atom or a methyl group, n is an integer of 0 or more and 5 or less,
in formular (b2g), R² is an alkyl group having 2 or more carbon atoms which may have a substituent, a cycloalkyl group which may have a substituent, or a group represented by —R³—Ar, R³ is a single bond or a methylene group, Ar is an aromatic group which may have a substituent,
in formula (b2g) and formula (b2m), R^{b2} is a hydrogen atom, an alkyl group having 1 or more and 5 or less carbon atoms, or a halogenated alkyl group having 1 or more and 5 or less carbon atoms, and
x represents a molar ratio and is more than 0 and 0.8 or less.]

A second aspect relates to a method for producing a structure having a phase-separated structure, the method including: applying the resin composition for forming a phase-separated structure as described in the first aspect onto a support to form a layer containing a block copolymer; and subjecting the layer containing the block copolymer to phase separation.

A third aspect relates to a block copolymer including: a first block; and a second block,
the first block being composed of a polymer having a repeating structure of a constituent unit represented by the following general formula (b1),
the second block being composed of a random copolymer having a structure in which a constituent unit represented by the following general formula (b2m) and a constituent unit represented by the following general formula (b2g) are randomly arranged.

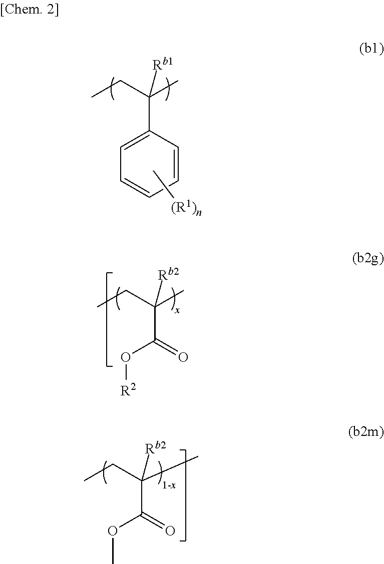

[wherein in formular (b1), R¹ is an alkyl group, R^{b1} is a hydrogen atom or a methyl group, n is an integer of 0 or more and 5 or less,
in formular (b2g), R² is an alkyl group having 2 or more carbon atoms which may have a substituent, a cycloalkyl group which may have a substituent, or a group represented by —R³—Ar, R³ is a single bond or a methylene group, Ar is an aromatic group which may have a substituent,
in formula (b2g) and formula (b2m), R^{b2} is a hydrogen atom, an alkyl group having 1 or more and 5 or less carbon atoms, or a halogenated alkyl group having 1 or more and 5 or less carbon atoms, and
x represents a molar ratio and is more than 0 and 0.8 or less.]

According to the present invention, it is possible to provide a resin composition for forming a phase-separated structure capable of forming a phase-separated structure which is excellent in vertical orientation and of which occurrence of defects is suppressed, a method for producing a structure having a phase-separated structure using the same, and a block copolymer for use in the resin composition for forming a phase-separated structure.

### BRIEF DESCRIPTION OF THE DRAWINGS

FIG. 1 is a schematic process diagram illustrating an exemplary embodiment of a method for producing a structure having a phase-separated structure; and

FIG. 2 is a diagram illustrating an exemplary embodiment of an optional step.

### DETAILED DESCRIPTION OF THE INVENTION

Hereinafter, embodiments of the present invention will be described in detail, but the present invention is not limited to the following embodiments, and can be implemented with modifications as appropriate within the scope of the object of the present invention.

### <<Resin Composition for Forming Phase-Separated Structure>

The resin composition for forming a phase-separated structure contains a block copolymer having a first block and a second block. The first block is composed of a polymer having a repeating structure of a constituent unit represented by the following general formula (b1). The second block is composed of a random copolymer having a structure in which a constituent unit represented by the following general formula (b2m) and a constituent unit represented by the following general formula (b2g) are randomly arranged.

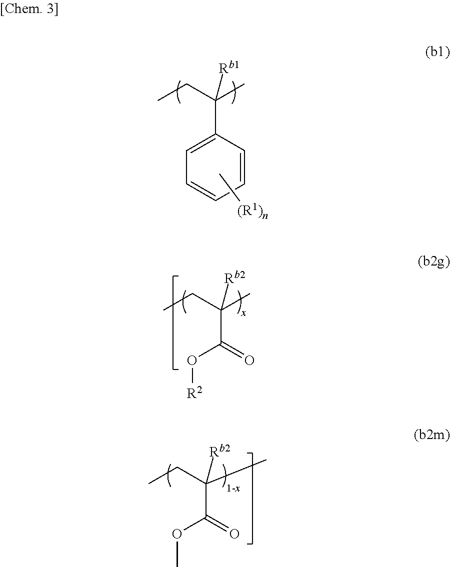

[wherein in formula (b1), R¹ is an alkyl group, R^{b1} is a hydrogen atom or a methyl group, n is an integer of 0 or more and 5 or less,
in formula (b2g), R² is an alkyl group having 2 or more carbon atoms which may have a substituent, a cycloalkyl group which may have a substituent, or a group represented by —R³—Ar, R³ is a single bond or a methylene group, Ar is an aromatic group which may have a substituent,
in formula (b2g) and formula (b2m), R^{b2} is a hydrogen atom, an alkyl group having 1 or more and 5 or less carbon atoms, or a halogenated alkyl group having 1 or more and 5 or less carbon atoms, and
x represents a molar ratio and is more than 0 and 0.8 or less.]

The block copolymer has the second block composed of the random copolymer having a structure in which the constituent unit represented by the following general formula (b2m) and the constituent unit represented by the following general formula (b2g) are randomly arranged, and thus an interaction parameter (χ) is small. It is generally said that a phase separation rate is reduced as the interaction parameter increases. Therefore, as a result of the phase separation rate being improved by using a block copolymer having a small interaction parameter, it is considered that the vertical orientation is improved and occurrence of defects can be suppressed.

In the general formula (b1), the general formula (b2g), and the general formula (b2m), a plurality of R¹, a plurality of R², a plurality of R^{b1}, and a plurality of R^{b2} may be the same as or different from each other.

### <Block Copolymer>

### [First Block]

The first block is composed of a polymer having a repeating structure of a constituent unit represented by the following general formula (b1) (hereinafter, also referred to as constituent unit (b1)).

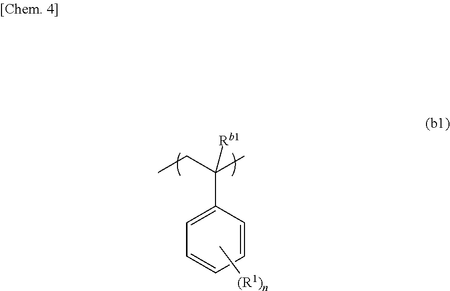

[wherein in formula (b1), R¹ is an alkyl group, R^{b1} is a hydrogen atom or a methyl group, and n is an integer of 0 or more and 5 or less.]

The number of carbon atoms of the alkyl group as R¹ is preferably 1 or more and 10 or less, more preferably 1 or more and 5 or less, and further preferably 1 or more and 3 or less. Examples of the alkyl group as R¹ include a methyl group, an ethyl group, an n-propyl group, an isopropyl group, an n-butyl group, a sec-butyl group, an isobutyl group, and a tert-butyl group.

n is preferably an integer of 0 or more and 3 or less, more preferably 0 or 1, and further preferably 0.

### [Second Block]

The second block is composed of a random copolymer having a structure in which a constituent unit represented by the following general formula (b2m) (hereinafter, also referred to as constituent unit (b2m)) and a constituent unit represented by the following general formula (b2g) (hereinafter, also referred to as constituent unit (b2g)) are randomly arranged.

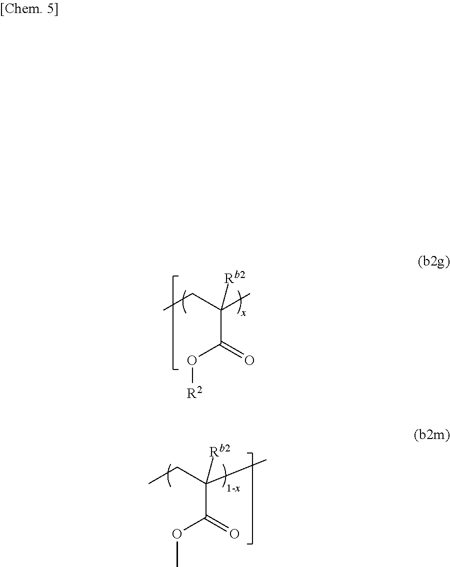

[wherein in formula (b2g), R² is an alkyl group having 2 or more carbon atoms which may have a substituent, a cycloalkyl group which may have a substituent, or a group represented by —R³—Ar, R³ is a single bond or a methylene group, Ar is an aromatic group which may have a substituent,
in formula (b2g) and formula (b2m), R^{b2} is a hydrogen atom, an alkyl group having 1 or more and 5 or less carbon atoms, or a halogenated alkyl group having 1 or more and 5 or less carbon atoms, and
x represents a molar ratio and is more than 0 and 0.8 or less.]
   (Constituent Unit (b2g))

The number of carbon atoms of the alkyl group as R² is preferably 2 or more and 30 or less, more preferably 2 or more and 20 or less, and further preferably 2 or more and 10 or less. The number of carbon atoms does not include the number of carbon atoms of the substituent. The alkyl group as R² may be linear or branched, but is preferably linear. Examples of the alkyl group as R² include an ethyl group, an n-propyl group, an isopropyl group, an n-butyl group, an n-pentyl group, an n-hexyl group, an n-heptyl group, an n-octyl group, an n-nonyl group, and an n-decyl group.

The number of carbon atoms of the cycloalkyl group as R² is preferably 3 or more and 10 or less, more preferably 4 or more and 8 or less, and further preferably 5 or more and 7 or less. The number of carbon atoms does not include the number of carbon atoms of the substituent. Examples of the cycloalkyl group as R² include a cyclopentyl group, a cyclohexyl group, and a cycloheptyl group.

Examples of the substituent which the alkyl group and the cycloalkyl group as R² may have include a halogen atom, an alkenyl group, a halogenated alkyl group, a silicon atom-containing group, an alicyclic hydrocarbon group, and an aromatic hydrocarbon group. Examples of the halogen atom as the substituent include a fluorine atom, a chlorine atom, a bromine atom, and an iodine atom, and a fluorine atom is preferred. The number of carbon atoms of the alkenyl group as the substituent is preferably 2 or more and 10 or less. The alkenyl group may be linear or branched. Examples of the alkenyl group include a vinyl group and a propenyl group. Examples of the halogenated alkyl group as the substituent include a group in which some or all of hydrogen atoms in the alkyl group as the substituent are substituted with halogen atoms. The halogenated alkyl group is preferably a fluorinated alkyl group, and particularly preferably a perfluoroalkyl group. Examples of the silicon atom-containing group as the substituent include: a silyl group such as a trimethylsilyl group, a triethylsilyl group, a t-butyldimethylsilyl group, or a triphenylsilyl group; and an alkyl group substituted with a silyl group such as a trimethylsilylmethyl group or a 2-trimethylsilylethyl group.

The alicyclic hydrocarbon group as the substituent may be a monocyclic group or a polycyclic group. The monocyclic alicyclic hydrocarbon group is preferably a group obtained by removing one hydrogen atom from a monocycloalkane. The number of carbon atoms of the monocycloalkane is preferably 3 or more and 6 or less. Examples of the monocycloalkane include cyclopentane and cyclohexane. The polycyclic alicyclic hydrocarbon group is preferably a group obtained by removing one hydrogen atom from a polycycloalkane. The number of carbon atoms of the polycycloalkane is preferably 7 or more and 30 or less. Specific examples of the polycycloalkane include: a polycycloalkane having a crosslinked ring polycyclic skeleton such as adamantane, norbornane, isobornane, tricyclodecane, or tetracyclododecane; and a polycycloalkane having a condensed ring polycyclic skeleton such as a cyclic group having a steroid skeleton.

The aromatic hydrocarbon group as the substituent may be a monocyclic aromatic group, a group formed by condensation of two or more aromatic hydrocarbon groups, or a group formed by bonding two or more aromatic hydrocarbon groups to a single bond. Examples of the aromatic hydrocarbon group include a phenyl group, a naphthyl group, and a biphenylyl group.

From the viewpoint of reducing the interaction parameter of the block copolymers and easily obtaining the effect of the present invention, it is preferable that the alkyl group as R² has no substituent.

The aromatic group as Ar may be an aromatic hydrocarbon group or an aromatic heterocyclic group, but is preferably an aromatic hydrocarbon group. The aromatic hydrocarbon group as Ar may be a monocyclic aromatic group, a group formed by condensation of two or more aromatic hydrocarbon groups, or a group formed by bonding two or more aromatic hydrocarbon groups to a single bond. Examples of the aromatic hydrocarbon group include a phenyl group, a naphthyl group, and a biphenyl. The aromatic heterocyclic group as Ar may be a monocyclic group or a polycyclic group. Examples of the aromatic heterocyclic group include a pyridyl group, a furyl group, a thienyl group, an imidazolyl group, a pyrazolyl group, an oxazolyl group, a thiazolyl group, an isoxazolyl group, an isothiazolyl group, a benzoxazolyl group, a benzothiazolyl group, and a benzimidazolyl group.

Examples of the substituent which the aromatic group as Ar may have include a halogen atom, an alkyl group, an alkenyl group, a halogenated alkyl group, an alicyclic hydrocarbon group, and an aromatic hydrocarbon group. The number of carbon atoms of the alkyl group as the substituent is preferably 2 or more and 10 or less. The alkyl group may be linear or branched. Examples of the alkyl group include a methyl group, an ethyl group, an n-propyl group, an isopropyl group, an n-butyl group, a sec-butyl group, an isobutyl group, and a tert-butyl group. The halogen atom, the alkenyl group, the halogenated alkyl group, the alicyclic hydrocarbon group, and the aromatic hydrocarbon group as the substituent are the same as the halogen atom, the alkenyl group, the halogenated alkyl group, the alicyclic hydrocarbon group, and the aromatic hydrocarbon group which the alkyl group as R² may have as the substituent.

In the formula (b2g), examples of the alkyl group having 1 or more and 5 or less carbon atoms as R^{b2} include a methyl group, an ethyl group, a propyl group, an isopropyl group, an n-butyl group, a sec-butyl group, a tert-butyl group, an n-pentyl group, a neopentyl group, an isopentyl group, a sec-pentyl group, a 3-pentyl group, and a tert-pentyl group. The halogenated alkyl group having 1 or more and 5 or less carbon atoms is a group in which some or all of hydrogen atoms in an alkyl group having 1 or more and 5 or less carbon atoms are substituted with halogen atoms. The halogen atom is particularly preferably a fluorine atom.

In the formula (b2g), R^{b2} is preferably a hydrogen atom or an alkyl group having 1 or more and 5 or less carbon atoms, and from the viewpoint of industrial availability, is more preferably a hydrogen atom or a methyl group, and further preferably a methyl group.

(Constituent Unit (b2m))

R^{b2} in the formula (b2m) is the same as R^{b2} in the formula (b2g).

In the second block, the ratio (x in formula (b2g) and formula (b2m)) of the number of moles of the constituent unit represented by the formula (b2g) to the total number of moles of the constituent unit represented by the formula (b2g) and the constituent unit represented by the formula (b2m) is preferably 0.01 or more and 0.5 or less, more preferably 0.01 or more and 0.3 or less, and further preferably 0.01 or more and 0.1 or less, from the viewpoint that the effect of the present invention is more easily obtained.

The ratio of the number of moles of the constituent unit of the first block to the total number of moles of the constituent unit of the first block and the constituent unit of the second block is preferably 20 mol % or more and 80 mol % or less. The ratio of the number of moles of the constituent unit of the first block is more preferably 30 mol % or more, and further preferably 40 mol % or more. In addition, the ratio of the number of moles of the constituent unit of the second block is more preferably 75 mol % or less. In particular, the ratio of the number of moles of the constituent unit of the second block is preferably 45 mol % or more and 55 mol % or less, from the viewpoint of easily exhibiting a lamellar phase-separated structure. In addition, the ratio of the number of moles of the constituent unit of the second block is preferably 60 mol % or more and 75 mol % or less, from the viewpoint of easily exhibiting a cylindrical phase-separated structure.

The block copolymer may have other blocks in addition to the first block and the second block. In a preferred embodiment, the block copolymer is a diblock copolymer composed of a first block and a second block.

The number average molecular weight (Mn) of the block copolymer is preferably 50,000 or more and 500,000 or less, more preferably 100,000 or more and 300,000 or less, further preferably 100,000 or more and 200,000 or less, and particularly preferably 120,000 or more and 180,000 or less, from the viewpoint of more easily exhibiting the effect of the present invention. A molecular-weight dispersion degree (Mw/Mn) of each block constituting the block copolymer is preferably 1.0 or more and 1.5 or less, more preferably 1.0 or more and 1.4 or less, and further preferably 1.0 or more and 1.3 or less. In the present description, the “number average molecular weight” (Mn) and the “weight average molecular weight” (Mw) mean a number average molecular weight and a weight average molecular weight in terms of standard polystyrene obtained by size-exclusion chromatography (SEC) measurement, unless otherwise specified. When a value of Mn or Mw is followed by a unit (gmol⁻¹), the value represents a molar mass.

### <Homopolymer>

The resin composition for forming a phase-separated structure preferably contains a homopolymer. As a result, the effect of the present invention is easily obtained particularly in the resin composition for forming a phase-separated structure exhibiting the cylindrical phase-separated structure.

The homopolymer is preferably at least one polymer selected from the group consisting of a polymer (I) having a repeating structure of the constituent unit represented by the general formula (b1) and a polymer (II) having a repeating structure of the constituent unit represented by the general formula (b2m). The constituent units of the polymer (I) and the polymer (II) may be the same as or different from the constituent unit of the block copolymer.

The polymer (I) is preferably polystyrene. The polymer (II) is preferably polymethyl methacrylate.

The number average molecular weight (Mn) of the homopolymer is preferably 500 or more and 50,000 or less, more preferably 1,000 or more and 10,000 or less, and further preferably 1,000 or more and 5,000 or less.

A content of the homopolymer is preferably 20 parts by mass or more and 200 parts by mass or less, more preferably 50 parts by mass or more and 160 parts by mass or less, and further preferably 80 parts by mass or more and 140 parts by mass or less with respect to 100 parts by mass of a content of the block copolymer.

A content of the polymer (I) is preferably 30 parts by mass or more and 140 parts by mass or less, more preferably 50 parts by mass or more and 120 parts by mass or less, and further preferably 60 parts by mass or more and 100 parts by mass or less with respect to 100 parts by mass of a content of the block copolymer. A content of the polymer (II) is preferably 15 parts by mass or more and 80 parts by mass or less, more preferably 25 parts by mass or more and 60 parts by mass or less, and further preferably 30 parts by mass or more and 50 parts by mass or less with respect to 100 parts by mass of a content of the block copolymer.

### <Organic Solvent Component>

The resin composition for forming a phase-separated structure preferably contains an organic solvent. Any organic solvent may be used as an organic solvent component as long as it can dissolve each component to be used and form a homogeneous solution. In the related art, any organic solvent selected from known organic solvents as a solvent for a composition including a resin as a main component may be used.

Examples of the organic solvent component include a lactone such as γ-butyrolactone; a ketone such as acetone, methyl ethyl ketone, cyclohexanone, methyl-n-pentyl ketone, methyl isopentyl ketone, or 2-heptanone; a polyhydric alcohol such as ethylene glycol, diethylene glycol, propylene glycol, or dipropylene glycol; a polyhydric alcohol monoacetate such as ethylene glycol monoacetate, diethylene glycol monoacetate, propylene glycol monoacetate, or dipropylene glycol monoacetate; a derivative of a polyhydric alcohol such as compounds having an ether bond, such as a monoalkyl ether or a monophenyl ether, such as a monomethyl ether, monoethyl ether, monopropyl ether, or monobutyl ether of the polyhydric alcohol or a monoacetate of the polyhydric alcohol; [among them, propylene glycol monomethyl ether acetate (PGMEA) or propylene glycol monomethyl ether (PGME) is preferred]; a cyclic ether such as dioxane, or an ester other than a polyhydric alcohol monoacetate and a derivative of the polyhydric alcohols described above, such as methyl lactate, ethyl lactate (EL), methyl acetate, ethyl acetate, butyl acetate, methyl pyruvate, ethyl pyruvate, methyl methoxy propionate, or ethyl ethoxy propionate; and an aromatic organic solvent such as anisole, ethyl benzyl ether, cresyl methyl ether, diphenyl ether, dibenzyl ether, phenetole, butyl phenyl ether, ethyl benzene, diethyl benzene, pentyl benzene, isopropyl benzene, toluene, xylene, cymene, or mesitylene. The organic solvent component may be used alone, or two or more thereof may be used as a mixed solvent. Among them, propylene glycol monomethyl ether acetate (PGMEA), propylene glycol monomethyl ether (PGME), cyclohexanone, or ethyl lactate (EL) is preferred.

The organic solvent component contained in the resin composition for forming a phase-separated structure is not particularly limited. The organic solvent component is determined appropriately according to a coating film thickness such that the resin composition for forming a phase-separated structure has a concentration with which the component can be applied. The organic solvent component is generally used such that a solid content concentration of the resin composition for forming a phase-separated structure is in a range of 0.2% by mass or more and 70% by mass or less, and preferably 0.2% by mass or more and 50% by mass or less.

### <Other Components>

The resin composition for forming a phase-separated structure may contain a component other than the block copolymer, the homopolymer, and the organic solvent component described above. Examples of the other components include another resin, a surfactant, a dissolution inhibiting agent, a plasticizing agent, a stabilizing agent, a coloring agent, an anti-halation agent, a dye, a sensitizing agent, a base proliferating agent, or a basic compound.

### <<Method for Producing Structure Having Phase-Separated Structure>>

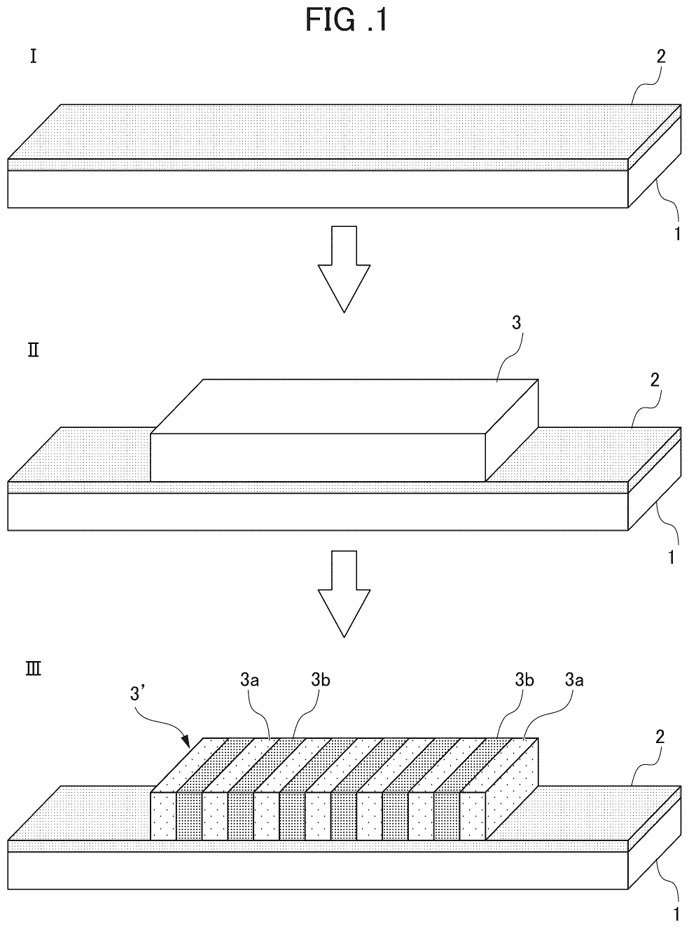

The method for producing a structure having a phase-separated structure includes applying the resin composition for forming a phase-separated structure onto a support to form a layer containing a block copolymer (hereinafter, referred to as “step (i)”), and subjecting the layer containing the block copolymer to phase separation (hereinafter, referred to as “step (ii)”). Hereinafter, such a method for producing a structure having a phase-separated structure will be described in detail with reference to FIG. 1. However, the method for producing a structure having a phase-separated structure is not limited to the specific aspect shown in FIG. 1.

FIG. 1 illustrates an exemplary embodiment of the method for producing a structure having a phase-separated structure. In the embodiment illustrated in FIG. 1, an undercoat agent is first applied onto a support 1 to form an undercoat agent layer 2 (FIG. 1(I)). Next, the resin composition for forming a phase-separated structure is applied onto the undercoat agent layer 2 to form a layer (BCP layer) 3 containing a block copolymer (FIG. 1(II); step (i) complete). Next, annealing treatment is performed by heating to separate the BCP layer 3 into a phase 3a and a phase 3b (FIG. 1(III); step (ii)). According to such a production method of the embodiment, that is, the production method including the step (i) and the step (ii), a structure 3′ having a phase-separated structure is produced on the support 1 on which the undercoat agent layer 2 is formed.

<Step (i)>

In the step (i), the resin composition for forming a phase-separated structure is applied onto the support 1 to form the BCP layer 3. In the embodiment illustrated in FIG. 1, the undercoat agent is first applied onto the support 1 to form the undercoat agent layer 2. By providing the undercoat agent layer 2 on the support 1, a hydrophilic-hydrophobic balance between a surface of the support 1 and the layer (BCP layer) 3 containing the block copolymer can be achieved. That is, when the undercoat agent layer 2 contains a resin component having a constituent unit constituting the first block, adhesion between a phase composed of the first block in the BCP layer 3 and the support 1 is improved. When the undercoat agent layer 2 contains a resin component having a constituent unit constituting the second block, adhesion between a phase composed of the second block in the BCP layer 3 and the support 1 is improved. Accordingly, a phase-separated structure oriented in a direction perpendicular to the surface of the support 1 is likely to be formed by the phase separation of the BCP layer 3.

### Undercoat Agent:

A resin composition can be used as the undercoat agent. The resin composition for the undercoat agent can be appropriately selected from known resin compositions to be used for forming a thin film in the related art depending on a kind of a block constituting a block copolymer. The resin composition for the undercoat agent may be, for example, a thermopolymerizable resin composition or a photosensitive resin composition such as a positive-type resist composition or a negative-type resist composition. Further, a non-polymerizable film formed by applying a compound serving as a surface-treating agent may also be used as an undercoat agent layer. For example, a siloxane-based organic monomolecular film formed by applying phenethyltrichlorosilane, octadecyltrichlorosilane, hexamethyldisilazane, or the like as a surface-treating agent can also be suitably used as the undercoat agent layer.

Examples of such a resin composition include a resin composition containing a resin having both constituent units constituting the first block and the second block, respectively, and a resin composition containing a resin having all constituent units having high affinity for respective blocks constituting the block copolymer. For example, a composition containing a resin having both styrene and methyl methacrylate as a constituent unit, or a compound or a composition including both a moiety having a high affinity with styrene such as an aromatic ring and a moiety having a high affinity with methyl methacrylate (highly polar functional group or the like) is preferably used as the resin composition for the undercoat agent. Examples of the resin having both styrene and methyl methacrylate as a constituent unit include a random copolymer of styrene and methyl methacrylate, or an alternating polymer of styrene and methyl methacrylate (polymer in which each monomer is alternately copolymerized). Further, examples of the composition including both a moiety having a high affinity with styrene and a moiety having a high affinity with methyl methacrylate include a composition containing a resin obtained by polymerizing at least a monomer having an aromatic ring and a monomer having a highly polar functional group as monomers. Examples of the monomer having an aromatic ring include a monomer having, an aryl group in which one hydrogen atom is removed from an aromatic hydrocarbon ring such as a phenyl group, a biphenyl group, a fluorenyl group, a naphthyl group, an anthryl group, or a phenanthryl group, or a heteroaryl group in which some of carbon atoms constituting a ring on any of the above-mentioned groups is substituted with a heteroatom such as an oxygen atom, a sulfur atom, or a nitrogen atom. Further, examples of the monomer having a highly polar functional group include a monomer having a trimethoxysilyl group, a trichlorosilyl group, an epoxy group, a glycidyl group, a carboxy group, a hydroxy group, a cyano group, or a hydroxyalkyl group in which some of hydrogen atoms in an alkyl group is substituted with a hydroxy group. Further, examples of the compound including both a moiety having a high affinity with styrene and a moiety having a high affinity with methyl methacrylate include a compound including both an aryl group such as phenethyltrichlorosilane and a highly polar functional group; or a compound including both an alkyl group such as an alkylsilane compound and a highly polar functional group.

The resin composition for the undercoat agent can be produced by dissolving the above-described resin in a solvent. Any solvent may be used as such a solvent as long as the solvent can dissolve each component to be used and form a homogeneous solution. For example, the same organic solvent component as one exemplified in the above-mentioned description for the resin composition for forming a phase-separated structure may be used.

A type of the support 1 is not particularly limited as long as the resin composition can be applied on the surface of the support 1. Examples thereof include a substrate made of an inorganic material such as a silicon, a metal (copper, chromium, iron, aluminum, or the like), glass, titanium oxide, silica, or mica; a substrate made of an oxide such as SiO₂; a substrate made of a nitride such as SiN; a substrate made of an oxynitride such as SiON; or a substrate made of an organic material such as acryl resin, polystyrene, cellulose, cellulose acetate, or a phenolic resin. Among them, a silicon substrate (Si substrate) or a metal substrate is suitable, a Si substrate or a copper substrate (Cu substrate) is more suitable, and a Si substrate is particularly suitable. A size or a shape of the support 1 is not particularly limited. The support 1 does not necessarily have a smooth surface, and substrates having various shapes can be appropriately selected. For example, a substrate having a curved surface, a flat plate having an uneven surface, or a flaky substrate may be used.

An inorganic and/or organic film may be provided on the surface of the support 1. Examples of the inorganic film include an inorganic antireflection film (inorganic BARC). Examples of the organic film include an organic antireflection film (organic BARC). The inorganic film can be formed, for example, by applying an inorganic antireflection film composition such as a silicon-based material on a support and baking the resultant. The organic film can be formed, for example, by applying, on a substrate using a spinner or the like, a material for forming an organic film in which a resin component or the like constituting the organic film is dissolved in an organic solvent, and baking the resultant under heating conditions of preferably 200° C. or higher and 300° C. or lower for preferably 30 seconds or more and 300 seconds or less, and more preferably for 60 seconds or more and 180 seconds or less. This material for forming an organic film does not necessarily need sensitivity to light or electron beams like a resist film, and may or may not have the sensitivity. Specifically, a resist or a resin generally used for producing a semiconductor element or a liquid crystal display element may be used. Further, the material for forming an organic film is preferably a material capable of forming an organic film that can be subjected to etching, particularly dry-etching such that an organic film pattern may be formed by etching the organic film using a pattern formed by processing the BCP layer 3 and made of the block copolymer and transferring the pattern to the organic film. Among them, a material capable of forming an organic film that can be subjected to etching such as oxygen plasma etching is preferably used. Such a material for forming an organic film may be a material used for forming an organic film such as an organic BARC in the related art. Examples thereof include ARC series manufactured by Nissan Chemical Corporation, AR series manufactured by Rohm and Haas Japan Ltd., or SWK series manufactured by TOKYO OHKA KOGYO CO., LTD.

A method for forming the undercoat agent layer 2 by applying the undercoat agent on the support 1 is not particularly limited, and may be any known method in the related art. For example, the undercoat agent layer 2 can be formed by applying the undercoat agent on the support 1 using a known method in the related art such as a spin coating or use of a spinner to form a coated film, and drying the coated film. A method for drying the coated film is not limited as long as a solvent contained in the undercoat agent can be volatilized, and, for example, a method for baking may be used. In this case, a baking temperature is preferably 80° C. or higher and 300° C. or lower, more preferably 180° C. or higher and 270° C. or lower, and further preferably 220° C. or higher and 250° C. or lower. A baking time is preferably 30 seconds or more and 600 seconds or less, and more preferably 60 seconds or more and 600 seconds or less. A thickness of the undercoat agent layer 2 after drying the coated film is preferably about 10 nm or more and 100 nm or less, and more preferably about 40 nm or more and 90 nm or less.

The surface of the support 1 may be previously cleaned before the undercoat agent layer 2 is formed on the support 1. Cleaning of the surface of the support 1 improves coatability of the undercoat agent. A known cleaning treatment method in the related art can be used, and examples thereof include an oxygen plasma treatment, an ozone oxidation treatment, an acid alkali treatment, or a chemical modification treatment.

After the undercoat agent layer 2 is formed, the undercoat agent layer 2 may be rinsed with a rinsing liquid such as a solvent, as necessary. Since an uncrosslinked portion or the like of the undercoat agent layer 2 is removed by the rinsing, affinity with at least one block constituting the block copolymer is improved, and thus, a phase-separated structure having a cylinder structure oriented in a direction perpendicular to the surface of the support 1 is likely to be formed. The rinsing liquid may be any liquid as long as the liquid can dissolve the uncrosslinked portion and, for example, a solvent such as propylene glycol monomethyl ether acetate (PGMEA), propylene glycol monomethyl ether (PGME), or ethyl lactate (EL), or a commercially available thinner liquid may be used. After the cleaning, post-baking may be performed in order to volatilize the rinsing liquid. A temperature condition during the post-baking is preferably 80° C. or higher and 300° C. or lower, and more preferably 100° C. or higher and 270° C. or lower. A baking time is preferably 30 seconds or more and 500 seconds or less, and more preferably 60 seconds or more and 240 seconds or less. A thickness of the undercoat agent layer 2 after such post-baking is preferably about 1 nm or more and 10 nm or less, and more preferably about 2 nm or more and 7 nm or less.

Next, the layer (BCP layer) 3 containing the block copolymer is formed on the undercoat agent layer 2. The method for forming the BCP layer 3 on the undercoat agent layer 2 is not particularly limited, and examples thereof include a method in which the resin composition for forming a phase-separated structure of the above-described embodiment is applied onto the undercoat agent layer 2 by a known method in the related art such as spin coating or use of a spinner to form a coating film, and drying the coating film.

Any thickness can be used as a thickness of the BCP layer 3 as long as the thickness is sufficient for phase separation to occur, and considering a type of the support 1, or a size of a structural period or uniformity of a nanostructure of the phase-separated structure to be formed, or the like, the thickness is preferably 20 nm or more and 100 nm or less, and more preferably 20 nm or more and 80 nm or less. For example, when the support 1 is a Si substrate, the thickness of the BCP layer 3 is preferably adjusted to 10 nm or more and 100 nm or less, and more preferably 20 nm or more and 80 nm or less.

<Step (ii)>

In the step (ii), the BCP layer 3 formed on the support 1 is phase-separated. After the step (i), the support 1 is subjected to annealing treatment by heating to form a phase-separated structure in which at least a part of the surface of the support 1 is exposed by selective removal of the block copolymer. That is, the structure 3′ having the phase-separated structure in which the phase 3a and the phase 3b are phase-separated is produced on the support 1. A temperature condition during the annealing treatment is preferably a glass transition temperature of the block copolymer used or higher and lower than a thermal decomposition temperature thereof, and for example, when the block copolymer is a polystyrene-polymethyl methacrylate (PS-PMMA) block copolymer (mass average molecular weight: 5,000 or more and 100,000 or less), the temperature condition is preferably 180° C. or higher and 270° C. or lower. A heating time is preferably 30 seconds or more and 3,600 seconds or less. The annealing treatment is preferably performed in a less reactive gas such as nitrogen.

### <Optional Step>

The method for producing a structure having a phase-separated structure is not limited to the above-described embodiment and may include a step (optional step) other than the step (i) and the step (ii).

Such an optional step includes a step of selectively removing a phase constituted by at least one of the first block and the second block constituting the block copolymer from the BCP layer 3 (hereinafter, referred to as “step (iii)”), a guide pattern formation step, or the like.

Regarding Step (iii)

In the step (iii), a phase constituted by at least one of the first block and the second block constituting the block copolymer is selectively removed from the BCP layer formed on the undercoat agent layer 2. As a result, a fine pattern (polymer nanostructure) is formed.

Examples of the method for selectively removing the phase constituted by the block include a method for subjecting the BCP layer to an oxygen plasma treatment or a method for subjecting the BCP layer to a hydrogen plasma treatment. For example, when the BCP layer containing the block copolymer is phase-separated and then the BCP layer is subjected to an oxygen plasma treatment, a hydrogen plasma treatment, or the like, a phase constituted by a first block is not selectively removed, but a phase constituted by a second block is selectively removed.

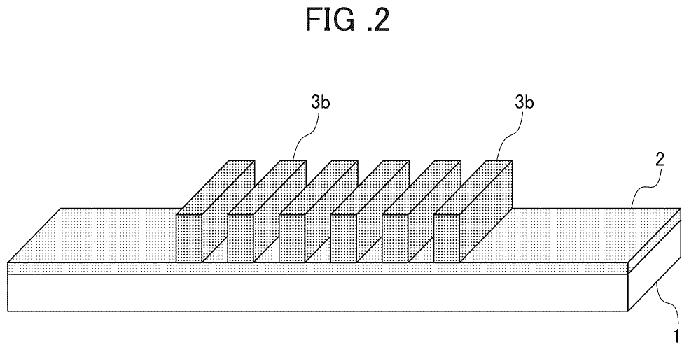

FIG. 2 illustrates an exemplary embodiment of the step (iii). In the embodiment illustrated in FIG. 2, the structure 3′ produced on the support 1 in the step (ii) is subjected to an oxygen plasma treatment to selectively remove the phases 3a, and a pattern (polymer nanostructure) constituted by the phases 3b apart from each other is formed. In this case, the phase 3b is the phase constituted by the first block, and the phase 3a is the phase constituted by the second block.

The support 1 with the pattern formed by the phase separation of the BCP layer 3 formed of the block copolymer as described above can be directly used, or a shape of the pattern (polymer nanostructure) on the support 1 can be changed by further heating. A temperature condition during the heating is preferably a glass transition temperature of the block copolymer used or higher and lower than a thermal decomposition temperature thereof. The heating is preferably performed in a less reactive gas such as nitrogen.

### Regarding Guide Pattern Formation Step

The method for producing a structure having a phase-separated structure may include a step of providing a guide pattern on the undercoat agent layer (guide pattern formation step) between the step (i) and the step (ii) described above. This allows an array structure of the phase-separated structure to be controlled. For example, even in the case of a block copolymer from which a fingerprint-shaped phase-separated structure is randomly formed when a guide pattern is not provided, a groove structure of a resist film can be provided on a surface of the undercoat agent layer to obtain a phase-separated structure oriented along the groove. According to this principle, a guide pattern may be provided on the undercoat agent layer 2. Further, when a surface of the guide pattern has an affinity with any of blocks constituting the block copolymer, a phase-separated structure having a cylinder structure oriented in a direction perpendicular to the surface of the support is likely to be formed.

The guide pattern can be formed using, for example, a resist composition. For the resist composition for forming the guide pattern, a resist composition having an affinity with any of blocks constituting the block copolymer can be appropriately selected from resist compositions to be generally used for forming a resist pattern or a modified product thereof. The resist composition may be either a positive-type resist composition that forms a positive-type pattern in which an exposed area of a resist film is dissolved and removed, or a negative-type resist composition that forms a negative-type pattern in which an unexposed area of a resist film is dissolved and removed, but a negative-type resist composition is preferred. The negative-type resist composition is preferably a resist composition that contains, for example, an acid-generating agent and a base material component having a solubility in an organic solvent-containing developing solution that is reduced under action of an acid, the base material component containing a resin component that has a constituent unit degraded under the action of an acid to have an increased polarity. After a BCP composition is poured onto the undercoat agent layer on which the guide pattern is formed, an annealing treatment is performed to cause phase separation. Therefore, a composition capable of forming a resist film having excellent solvent resistance and heat resistance is preferably used as the resist composition for forming the guide pattern.

As described above, the present inventors provide the following aspects (1) to (8).
(1) A resin composition for forming a phase-separated structure, the resin composition including: a block copolymer having a first block and a second block, the first block being composed of a polymer having a repeating structure of a constituent unit represented by the following general formula (b1), the second block being composed of a random copolymer having a structure in which a constituent unit represented by the following general formula (b2m) and a constituent unit represented by the following general formula (b2g) are randomly arranged,

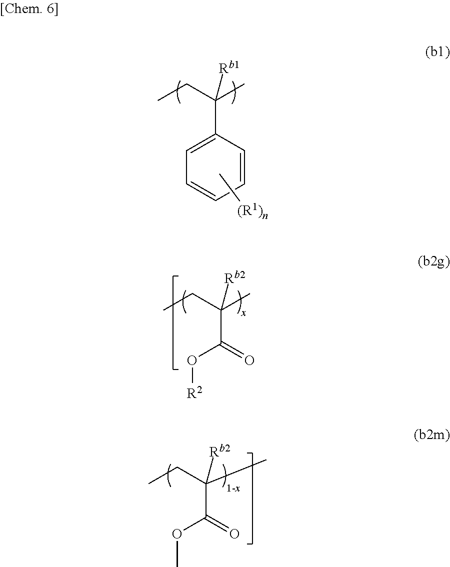

[wherein in formula (b1), R¹ is an alkyl group, R^{b1} is a hydrogen atom or a methyl group, n is an integer of 0 or more and 5 or less,
in formula (bg), R² is an alkyl group having 2 or more carbon atoms which may have a substituent, a cycloalkyl group which may have a substituent, or a group represented by —R³—Ar, R³ is a single bond or a methylene group, Ar is an aromatic group which may have a substituent,
in formula (b2g) and formula (b2m), R^{b2} is a hydrogen atom, an alkyl group having 1 or more and 5 or less carbon atoms, or a halogenated alkyl group having 1 or more and 5 or less carbon atoms, and
x represents a molar ratio and is more than 0 and 0.8 or less.]
(2) The resin composition for forming a phase-separated structure as described in aspect (1), in which a ratio of the number of moles of the constituent unit of the first block to the total number of moles of the constituent unit of the first block and the constituent unit of the second block is 20 mol % or more and 80 mol % or less.
(3) The resin composition for forming a phase-separated structure as described in aspect (1), further containing a homopolymer.
(4) The resin composition for forming a phase-separated structure as described in aspect (3), in which the homopolymer contains a polymer having a repeating structure of the constituent unit represented by the general formula (b1).
(5) The resin composition for forming a phase-separated structure as described in aspect (3) or (4), in which a number average molecular weight of the homopolymer is 1,000 or more.
(6) The resin composition for forming a phase-separated structure as described in any one of aspects (3) to (5), in which a content of the homopolymer is 20 parts by mass or more and 200 parts by mass or less with respect to 100 parts by mass of a content of the block copolymer.
(7) A method for producing a structure having a phase-separated structure, the method including: applying the resin composition for forming a phase-separated structure as described in any one of aspects (1) to (6) on a support to form a layer containing the block copolymer; and subjecting the layer containing the block copolymer to phase separation.
(8) A block copolymer including: a first block; and a second block, the first block being composed of a polymer having a repeating structure of a constituent unit represented by the following general formula (b1), the second block being composed of a random copolymer having a structure in which a constituent unit represented by the following general formula (b2m) and a constituent unit represented by the following general formula (b2g) are randomly arranged,

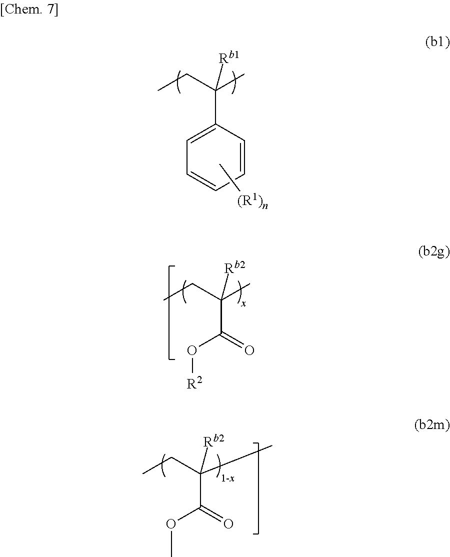

[wherein in formula (b1), R¹ is an alkyl group, R^{b1} is a hydrogen atom or a methyl group, n is an integer of 0 or more and 5 or less,
in formula (b2g), R² is an alkyl group having 2 or more carbon atoms which may have a substituent, a cycloalkyl group which may have a substituent, or a group represented by —R³—Ar, R³ is a single bond or a methylene group, Ar is an aromatic group which may have a substituent,
in formula (b2g) and formula (b2m), R^{b2} is a hydrogen atom, an alkyl group having 1 or more and 5 or less carbon atoms, or a halogenated alkyl group having 1 or more and 5 or less carbon atoms, and
x represents a molar ratio and is more than 0 and 0.8 or less.]

### EXAMPLES

Hereinafter, the present invention will be described in more detail with reference to examples, but the present invention is not limited to these examples.

### (Synthesis of Block Copolymer: BCP (1))

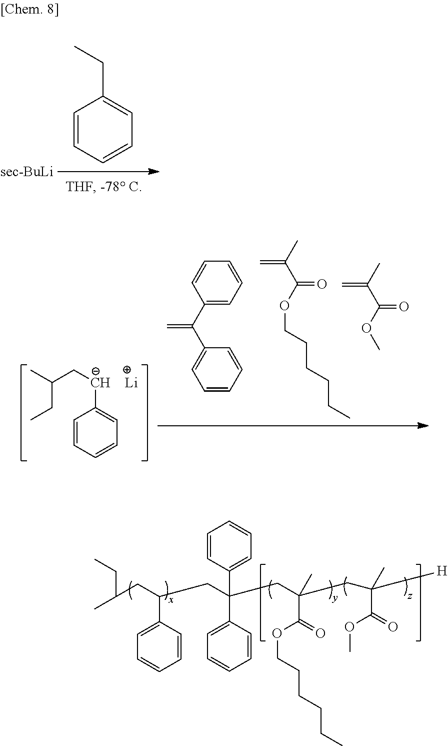

All anionic polymerization was performed under an argon atmosphere. 200 mL of tetrahydrofuran (THF) and lithium chloride (LiCl) (180 mg, 4.25 mmol) were transferred to a 300 mL Schlenk flask and cooled to −78° C. in a Coolnics bath. sec-butyllithium (sec-BuLi) (1.2 M of hexane/cyclohexane solution) was added to the Schlenk flask until a color of the solution changed to yellow. The Schlenk flask was removed from the Coolnics bath and warmed at room temperature until the solution became colorless. The Schlenk flask was again cooled to −78° C. in the Coolnics bath and sec-BuLi (0.245 mL, 0.53 mmol) was added as an initiator. Styrene (18.9 mL, 0.165 mol) was added to the Schlenk flask and stirred for 30 minutes. As a result, a solution having a color of bright orange was obtained. 1,1-diphenylethylene (DPE) (0.200 mL, 0.880 mmol) was added to the Schlenk flask, and the color of the solution changed to deep red. After stirring for 30 minutes, a monomer mixture of methyl methacrylate (MMA) (8.60 g, 0.085 mol) and hexyl methacrylate (0.47 g, 2.76 mmol) was added to the Schlenk flask and stirred for 120 minutes. The color of the solution changed from red to transparent. The polymerization was terminated by adding 3 mL of degassed methanol (MeOH) to the Schlenk flask as a terminator. The Schlenk flask was removed from the Coolnics bath, and the solution was poured into MeOH for reprecipitation. A precipitated solid was filtered and then dried under reduced pressure at 40° C. to obtain a white powder of a BCP (1) (23.8 g, 91% yield). Mn and a dispersion degree (PDI=Mw/Mn) of the BCP (1) measured by size-exclusion chromatography (SEC) were 158,000 gmol⁻¹ and 1.02, respectively.

¹H NMR (600 MHZ, deuterated acetone, δ, ppm): 0.84 to 1.03 (α-CH₃, PMMA and PHMA, —CH₂—(CH₂)₄—CH₃, PHMA), 1.23 to 2.23 (backbone, —CH₂—CH—, PS, —CH₂—C(CH₃)—, PMMA and PHMA, —CH₂—(CH₂)₄—CH₃, PHMA), 3.65 (—OCH₃, PMMA), 4.13 (—OCH₂—, PHMA), 6.36 to 7.35 (aromatic, PS)

### [Synthesis of BCPs (2) to (4)]

BCPs (2) to (4) were each synthesized in the same manner as in the synthesis of the BCP (1) using the same monomer as in the synthesis of the BCP (1).

### [Synthesis of BCP (5)]

BCP (5) was synthesized in the same manner as BCP (1), except that ethyl methacrylate was used instead of hexyl methacrylate.

¹H NMR (600 MHZ, deuterated acetone, δ, ppm): 0.84 to 1.03 (α-CH₃, PMMA and PEMA, —CH₂—CH₃, PEMA), 1.23 to 2.23 (backbone, —CH₂—CH—, PS, —CH₂—C(CH₃)—, PMMA and PEMA), 3.65 (—OCH₃, PMMA), 4.13 (—OCH₂—, PEMA), 6.36 to 7.35 (aromatic, PS)

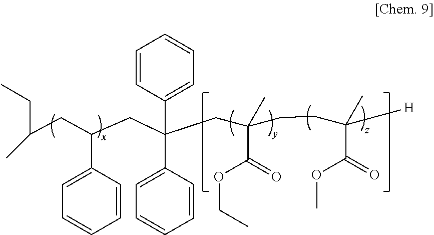

### [Synthesis of BCP (6)]

BCP (6) was synthesized in the same manner as BCP (1), except that butyl methacrylate was used instead of hexyl methacrylate.

¹H NMR (600 MHZ, deuterated acetone, δ, ppm): 0.84 to 1.03 (α-CH₃, PMMA and PBMA, —CH₂—(CH₂)₂—CH₃, PBMA), 1.23 to 2.23 (backbone, —CH₂—CH—, PS, —CH₂—C(CH₃)—, PMMA and PBMA, —CH₂—(CH₂)₂—CH₃, PBMA), 3.65 (—OCH₃, PMMA), 4.13 (—OCH₂—, PBMA), 6.36 to 7.35 (aromatic, PS)

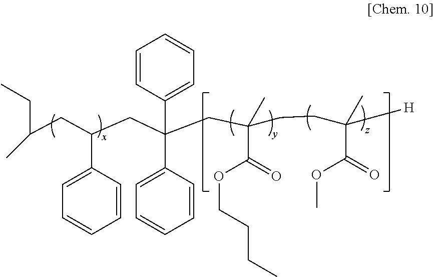

### [Synthesis of BCP (7)]

BCP (7) was synthesized in the same manner as BCP (1), except that cyclohexyl methacrylate was used instead of hexyl methacrylate.

¹H NMR (600 MHZ, deuterated acetone, δ, ppm): 0.84 to 1.03 (α-CH₃, PMMA and PCHMA), 1.23 to 2.23 (backbone, —CH₂—CH—, PS, —CH₂—C(CH₃)—, PMMA and PCHMA, —CH (CH₂—CH₂)—CH₂—CH₂—CH₂—), PCHMA), 3.65 (—OCH₃, PMMA), 4.13 (—OCH(CH₂—CH₂)—, PCHMA), 6.36 to 7.35 (aromatic, PS)

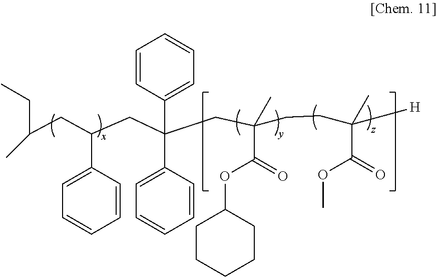

### BCPs (8) and (9): Block Copolymer of a Block Composed of Polystyrene and a Block Composed of Polymethyl Methacrylate

### <Measurement of Molar Ratio of Constituent Unit of Each Block>

By performing 1H-NMR measurement (600 MHZ, deuterated acetone) using an NMR device (manufactured by Bruker, equipped with CryoProbe), an integration ratio value (area ratio) was measured based on a chemical shift of the constituent unit of each block of the block copolymer, and a molar ratio of the constituent unit of each block was calculated.

Table 1 summarizes: a number average molecular weight (Mn) of each block copolymer synthesized above; a molecular-weight dispersion degree (PDI=Mw/Mn); a ratio (x:y:z) of the number of moles of the constituent unit (b1), the number of moles of the constituent unit (b2g), and the number of moles of the constituent unit (b2m) to the total number of moles of the respective constituent units; and a ratio (y/(y+z)) of the number of moles of the constituent unit (b2g) to the total number of moles of the constituent unit (b2g) and the constituent unit (b2m).

TABLE 1

| | Mn | PDI | x:y:z | y/(y + z) |
|---|---|---|---|---|
| BCP(1) | 158,000 | 1.02 | 65/1/34 | 0.03 |
| BCP(2) | 161,000 | 1.04 | 67/1/32 | 0.03 |
| BCP(3) | 164,000 | 1.03 | 69/1/30 | 0.03 |
| BCP(4) | 156,000 | 1.04 | 50/1/49 | 0.02 |
| BCP(5) | 158,000 | 1.02 | 65/1/34 | 0.03 |
| BCP(6) | 158,000 | 1.02 | 65/1/34 | 0.03 |
| BCP(7) | 158,000 | 1.02 | 65/1/34 | 0.03 |
| BCP(8) | 158,000 | 1.03 | 65/0/35 | — |
| BCP(9) | 156,000 | 1.03 | 50/0/50 | — |

### <Preparation of Resin Composition for Forming Phase-Separated Structure, and Production of Structure Having Phase-Separated Structure (1)>

A block copolymer (BCP), a homopolymer (HP), and an organic solvent component of types and amounts shown in Table 2 were mixed and dissolved to prepare a resin composition for forming a phase-separated structure (solid content concentration: 1% by mass) of each example.

TABLE 2

| | | | | Organic solvent |
|---|---|---|---|---|
| | BCP | HP(PS) | HP(PMMA) | component |
| Example 1 | BCP(1) | PS-2k | PMMA-2k | (S)-1 |
| | [100] | [78] | [42] | [21780] |
| Example 2 | BCP(2) | PS-2k | PMMA-2k | (S)-1 |
| | [100] | [80] | [40] | [21780] |
| Example 3 | BCP(3) | PS-2k | PMMA-2k | (S)-1 |
| | [100] | [83] | [37] | [21780] |
| Example 4 | BCP(4) | — | — | (S)-1 |
| | [100] | | | [9900] |
| Example 5 | BCP(5) | PS-2k | PMMA-2k | (S)-1 |
| | [100] | [78] | [42] | [21780] |
| Example 6 | BCP(6) | PS-2k | PMMA-2k | (S)-1 |
| | [100] | [78] | [42] | [21780] |
| Example 7 | BCP(7) | PS-2k | PMMA-2k | (S)-1 |
| | [100] | [78] | [42] | [21780] |
| Example 8 | BCP(5) | PS-2k | PMMA-2k | (S)-1 |
| | [100] | [33] | [17] | [14850] |
| Example 9 | BCP(5) | PS-2k | PMMA-2k | (S)-1 |
| | [100] | [39] | [21] | [15840] |
| Example 10 | BCP(5) | PS-2k | PMMA-2k | (S)-1 |
| | [100] | [65] | [35] | [19800] |
| Example 11 | BCP(5) | PS-2k | PMMA-2k | (S)-1 |
| | [100] | [130] | [70] | [29700] |
| Comparative | BCP(8) | PS-2k | PMMA-2k | (S)-1 |
| Example 1 | [100] | [78] | [42] | [21780] |
| Comparative | BCP(9) | — | — | (S)-1 |
| Example 2 | [100] | | | [9900] |

In Table 2, each abbreviation has the following meaning. The numerical value in [ ] is a blending amount (part(s) by mass).
BCPs (1) to (9): BCPs (1) to (9) described above
PS-2k: polystyrene (number average molecular weight: 2,000)
PMMA-2k: polymethyl methacrylate (number average molecular weight: 2,000)
(S)-1: propylene glycol monomethyl ether acetate (PGMEA)

A neutralization film composition solution (undercoat agent) prepared in a propylene glycol monomethyl ether acetate (PGMEA) solution having a concentration of 2 wt % was applied to a 12-inch silicon wafer at 1,500 rpm using a spinner, and baked at 250° C. for 300 seconds under a nitrogen atmosphere and dried, thereby forming a layer (undercoat agent layer) formed of a neutralization film having a film thickness of 30 nm on a substrate. Next, a portion of the neutralization film other than a substrate adhesion portion was removed with an OK73 thinner (trade name, manufactured by TOKYO OHKA KOGYO CO., LTD.), post-baked at 100° C. for 60 seconds to spin coat a resin composition for purification of a phase-separated structure of each example on the layer formed of the neutralization film, and then soft-baked at 90° C. for 60 seconds to form a BCP layer having a film thickness of 30 nm. As the neutralization film composition solution, a PGMEA solution of a copolymer (St/MMA/HEMA=82/12/6 (mol %), number average molecular weight: 25,700, weight average molecular weight: 45,300, dispersion degree (PDI): 1.76) having a styrene (St) unit, a methyl methacrylate (MMA) unit, and a 2-hydroxyethyl methacrylate (HEMA) unit was used.

The formed BCP layer was annealed under a nitrogen atmosphere to form a phase-separated structure. A temperature and a time of the annealing were 200° C. and 15 minutes.

The substrate on which the phase-separated structure was formed was irradiated with ultraviolet rays (2172 nm, 160 mJ) under a nitrogen atmosphere using CLEAN TRACK LITHIUS Pro-Z (manufactured by Tokyo Electron Limited.). Thereafter, development was performed with isopropyl alcohol to selectively remove a phase containing a constituent unit derived from methyl methacrylate, thereby forming a pattern.

### [Measurement of L₀ of Structure]

Each of the formed patterns was subjected to image analysis using image analysis software (DSA-APPS, manufactured by Hitachi High-Tech Corporation) to determine an L₀ in an image of 1,350 nm square. Results thereof are shown in Table 3.

### [Observation of Morphology]

A surface (phase-separated state) of the obtained substrate was observed with a length-measuring SEM (scanning electron microscope, trade name: CG6300, manufactured by Hitachi High-Technologies Corporation, accelerating voltage: 800 eV, current value: 15 pA, Frame 256, magnification: 100 k (image of 1,350 nm square)), and the morphology of the phase-separated structure was confirmed. Results thereof are shown in Table 3 as “Morphology”.

### [Evaluation of Vertical Orientation]

A surface (phase-separated state) of the obtained substrate was observed with a length-measuring SEM (scanning electron microscope, trade name: CG6300, manufactured by Hitachi High-Technologies Corporation, accelerating voltage: 800 eV, current value: 15 pA, Frame 256, magnification: 100 k (image of 1,350 nm square)). As a result of such observation, phase separation performance was evaluated based on the following evaluation criteria. Results thereof are shown in Table 3 as “vertical orientation”.

### (Evaluation Criteria)

A: Vertical orientation was observed over the entire surface. A″: Vertical orientation was partially observed.
B: Vertical orientation was not observed.

### [Evaluation of Defect]

A surface (phase-separated state) of the obtained substrate was observed with a length-measuring SEM (scanning electron microscope, trade name: CG6300, manufactured by Hitachi High-Technologies Corporation, accelerating voltage: 800 eV, current value: 15 pA, Frame 256, magnification: 100 k (image of 1,350 nm square)) from above for 10 images at a magnification of 100,000 times, and the number of defects was counted. As a result of such counting, pattern defects were evaluated based on the following evaluation criteria. Results thereof are shown in Table 3 as “Defect”.

### (Evaluation Criteria)

A: Total number of defects is less than 100.
B: Total number of defects is 100 or more and less than 300.
C: Total number of defects is 300 or more

TABLE 3

| | | | Vertical | |
|---|---|---|---|---|
| | Lo(nm) | Morphology | orientation | Defect |
| Example 1 | 52.1 | Cylinder | A | A |
| Example 2 | 53.5 | Cylinder | A | A |
| Example 3 | 53.2 | Cylinder | A | A |
| Example 4 | 51.9 | Lamella | A | A |
| Example 5 | 53.5 | Cylinder | A | A |
| Example 6 | 52.9 | Cylinder | A | A |
| Example 7 | 52.0 | Cylinder | A | B |
| Example 8 | 57.1 | Cylinder | A | B |
| Example 9 | 56.5 | Cylinder | A | A |
| Example 10 | 54.5 | Cylinder | A | A |
| Example 11 | 50.3 | Cylinder | A | B |
| Comparative | 54.2 | Cylinder | A | C |
| Example 1 | | | | |
| Comparative | 54.0 | Lamella | A | C |
| Example 2 | | | | |

### <Preparation of Resin Composition for Forming Phase-Separated Structure, and Production of Structure Having Phase-Separated Structure (2)>

Resin compositions for forming a phase-separated structure in Examples 12 to 22 and Comparative Examples 3 and 4 (solid content concentration: 2% by mass) were each prepared by changing the organic solvent components in the resin compositions for forming a phase-separated structure of Examples 1 to 11 and Comparative Examples 1 and 2 to have amounts shown in Table 4.

TABLE 4

| | | | | Organic solvent |
|---|---|---|---|---|
| | BCP | HP(PS) | HP(PMMA) | component |
| Example 12 | BCP(1) | PS-2k | PMMA-2k | (S)-1 |
| | [100] | [78] | [42] | [10780] |
| Example 13 | BCP(2) | PS-2k | PMMA-2k | (S)-1 |
| | [100] | [80] | [40] | [10780] |
| Example 14 | BCP(3) | PS-2k | PMMA-2k | (S)-1 |
| | [100] | [83] | [37] | [10780] |
| Example 15 | BCP(4) | — | — | (S)-1 |
| | [100] | | | [4900] |
| Example 16 | BCP(5) | PS-2k | PMMA-2k | (S)-1 |
| | [100] | [78] | [42] | [10780] |
| Example 17 | BCP(6) | PS-2k | PMMA-2k | (S)-1 |
| | [100] | [78] | [42] | [10780] |
| Example 18 | BCP(7) | PS-2k | PMMA-2k | (S)-1 |
| | [100] | [78] | [42] | [10780] |
| Ezample 19 | BCP(5) | PS-2k | PMMA-2k | (S)-1 |
| | [100] | [33] | [17] | [7350] |
| Example 20 | BCP(5) | PS-2k | PMMA-2k | (S)-1 |
| | [100] | [39] | [21] | [7840] |
| Example 21 | BCP(5) | PS-2k | PMMA-2k | (S)-1 |
| | [100] | [65] | [35] | [9800] |
| Example 22 | BCP(5) | PS-2k | PMMA-2k | (S)-1 |
| | [100] | [130] | [70] | [14700] |
| Comparative | BCP(8) | FS-2k | PMMA-2k | (S)-1 |
| Example 3 | [100] | [78] | [42] | [10780] |
| Comparative | BCP(9) | — | — | (S)-1 |
| Example 4 | [100] | | | [4900] |

Abbreviations in Table 4 are the same as those in Table 2. The numerical value in [ ] is a blending amount (part(s) by mass).

A phase-separated structure was formed in the same manner as in Production of Structure Having Phase-separated Structure (1) except that a BCP layer having a film thickness of 60 nm was formed, and evaluation on vertical orientation and evaluation on defects were performed. Results thereof are shown in Table 5.

TABLE 5

| | Vertical orientation | Defect |
|---|---|---|
| Example 12 | A | A |
| Example 13 | A | A |
| Example 14 | A | A |
| Example 15 | A | A |
| Example 16 | A | A |
| Example 17 | A | A |
| Example 18 | A | B |
| Example 19 | A | B |
| Example 20 | A | A |
| Example 21 | A | A |
| Example 22 | A | B |
| Comparative Example 3 | A⁻ | C |
| Comparative Example 4 | A | C |

As shown in Tables 3 and 5, in Examples 1 to 22 in which a predetermined block copolymer was used, vertical orientation was observed over the entire surface, and the number of defects was small. On the other hand, in Comparative Examples 1 to 4 using a block copolymer in the related art, the number of defects was large. In particular, as can be seen from Comparative Example 3, when a cylindrical phase-separated structure is formed by a thick BCP layer, the vertical orientation is poor when the block copolymer in the related art is used, and the vertical orientation is excellent when a predetermined block copolymer is used.

What is claimed is:

1. A resin composition for forming a phase-separated structure, the resin composition comprising a block copolymer having a first block and a second block,
wherein the first block comprises a polymer having a repeating structure of a constituent unit represented by the following general formula (b1),
the second block comprises a random copolymer having a structure in which a constituent unit represented by the following general formula (b2m) and a constituent unit represented by the following general formula (b2g) are randomly arranged, 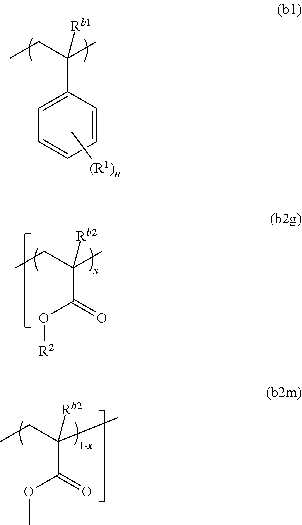
wherein in formula (b1), R¹ is an alkyl group, R^{b1} is a hydrogen atom or a methyl group, n is an integer of 0 or more and 5 or less,
in formula (b2g), R² is an alkyl group having 2 or more carbon atoms which may have a substituent, a cycloalkyl group which may have a substituent, or a group represented by —R³—Ar, R³ is a single bond or a methylene group, Ar is an aromatic group which may have a substituent,
in formula (b2g) and formula (b2m), R^{b2} is a hydrogen atom, an alkyl group having 1 or more and 5 or less carbon atoms, or a halogenated alkyl group having 1 or more and 5 or less carbon atoms, and
x represents a molar ratio and is more than 0 and 0.8 or less.

2. The resin composition for forming a phase-separated structure according to claim 1, wherein a ratio of the number of moles of the constituent unit of the first block to the total number of moles of the constituent unit of the first block and the constituent unit of the second block is 20 mol % or more and 80 mol % or less.

3. The resin composition for forming a phase-separated structure according to claim 1, further comprising a homopolymer.

4. The resin composition for forming a phase-separated structure according to claim 3, wherein the homopolymer comprises a polymer having a repeating structure of the constituent unit represented by the general formula (b1).

5. The resin composition for forming a phase-separated structure according to claim 3, wherein a number average molecular weight of the homopolymer is 1,000 or more.

6. The resin composition for forming a phase-separated structure according to claim 3, wherein a content of the homopolymer is 20 parts by mass or more and 200 parts by mass or less with respect to 100 parts by mass of a content of the block copolymer.

7. A method for producing a structure having a phase-separated structure, the method comprising:
applying the resin composition for forming a phase-separated structure according to claim 1 onto a support to form a layer comprising the block copolymer; and
subjecting the layer comprising the block copolymer to phase separation.

8. A block copolymer comprising a first block and a second block,
wherein the first block comprises a polymer having a repeating structure of a constituent unit represented by the following general formula (b1),
the second block comprises a random copolymer having a structure in which a constituent unit represented by the following general formula (b2m) and a constituent unit represented by the following general formula (b2g) are randomly arranged, 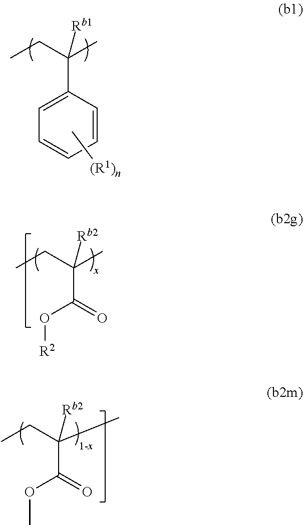
wherein in formula (b1), R¹ is an alkyl group, R^{b1} is a hydrogen atom or a methyl group, n is an integer of 0 or more and 5 or less,
in formula (b2g), R² is an alkyl group having 2 or more carbon atoms which may have a substituent, a cycloalkyl group which may have a substituent, or a group represented by —R³—Ar, R³ is a single bond or a methylene group, Ar is an aromatic group which may have a substituent,
in formula (b2g) and formula (b2m), R^{b2} is a hydrogen atom, an alkyl group having 1 or more and 5 or less carbon atoms, or a halogenated alkyl group having 1 or more and 5 or less carbon atoms, and
x represents a molar ratio and is more than 0 and 0.8 or less.
